(19) United States
(12) Patent Application Publication
(10) Pub. No.: US 2007/0062645 A1
(43) Pub. Date: Mar. 22, 2007

(54) PROCESSING APPARATUS

(75) Inventor: Yusuke Fukuchi, Tokyo (JP)

Correspondence Address: CANON U.S.A. INC. INTELLECTUAL PROPERTY DIVISION, 15975 ALTON PARKWAY, IRVINE, CA, 92618-3731, US

(73) Assignee: CANON KABUSHIKI KAISHA, Tokyo (JP)

(21) Appl. No.: 11/531,991

(22) Filed: Sep. 14, 2006

(30) Foreign Application Priority Data
Sep. 22, 2005 (JP) 2005-275047

(51) Int. Cl. H01L 21/306; C23C 16/00

(52) U.S. Cl. 156/345.24; 118/723 R

(57) ABSTRACT

A processing apparatus which can precisely control a radical flux over a broad range in radical treatment is provided. A surface of a substrate, such as a semiconductor, is processed with radicals in a treatment chamber. A gas inlet is disposed between a support for supporting the substrate and a radical-generating region where radicals are generated by a radical-forming portion. A first gas outlet is disposed at the side of the radical-generating region with respect to the gas inlet. A second gas outlet is disposed at the side of the support with respect to the gas inlet.

### BACKGROUND OF THE INVENTION

1. Field of the Invention

The present invention relates to processing apparatuses suitable for the formation of gate-insulating films used in semiconductor devices.

2. Description of the Related Art

Radicals are used in the fabrication of some semiconductor devices. For example, radicals are broadly used in processes such as etching, ashing, and film forming.

Recently, radical treatment has been applied to the formation of ultra-thin gate-insulating films and to surface modification in response to the requirement of microfabrication of semiconductor devices. In the processes of forming ultra-thin films and modifying surfaces, it is necessary to precisely control a radical flux applied to substrates to be processed so that the thickness of the formed films and the modification degrees of the surfaces are well controlled.

Here, a known plasma excitation apparatus for controlling a plasma flux applied to a substrate to be processed will be described with reference to FIG. 6.

This plasma excitation apparatus includes a treatment chamber 601 and a substrate-support 603 for supporting a substrate 602 to be processed. The substrate-support 603 is movable so that its distance from a radical-generating region 611 may be adjusted. The plasma excitation apparatus further includes a heater 604 for heating the substrate 602, gas outlets 606 for discharging a gas in the treatment chamber 601, and gas inlets 605 for introducing a plasma reaction gas, a power-supplying unit 608 for supplying power to the treatment chamber 601, and a flux-controlling flat plate 609 having a plurality of through-holes.

A substrate 602 is processed with plasma as follows: The treatment chamber 601 is evacuated through the gas outlets 606 to produce vacuum conditions in the chamber 601. Then, a reaction gas is introduced at a predetermined flow rate through the gas inlets 605 disposed at the bottom of the treatment chamber 601. The pressure in the treatment chamber 601 is maintained at a predetermined level by adjusting conductance valves (not shown) provided on the gas outlets 606. The treatment chamber 601 is supplied with necessary power for generating plasma from the power-supplying unit 608. The introduced reaction gas is excited and ionized by the generated plasma and reacts to generate radicals in the radical-generating region 611. The radicals process the surface of a substrate 602 placed on the substrate-support 603. At this stage, the radical flux to the substrate 602 can be controlled by the following methods:

(a) The physical distance between the radical-generating region 611 and the substrate 602 can be varied by changing the position of the substrate-support 603. Thus, the radical flux is controlled by adjusting the degree of radical inactivation during the radical transportation from the radical-generating region 611 to the substrate 602.

(b) The passage of the radicals is controlled by a plate having through-holes disposed between the radical-generating region 611 and the radical-treatment chamber 601 where the substrate 602 is placed. For example, the radical flux is controlled by changing the conductance of the conductance-controlling plate 609 having a plurality of through-holes.

(c) The power supplied by the power-introducing unit 608 for generating radicals is controlled to adjust the radical density to be generated. Thus, the radical flux is controlled.

(d) The pressure in the treatment chamber 601 is controlled to adjust the radical density in the treatment chamber 601. Thus, the radical flux is controlled.

However, these methods for controlling radical fluxes have some negative effects.

For example, in the method (a), it is necessary that the substrate 602 be separated from the radical-generating region 611 by a long distance for controlling a radical flux over a wide range. Therefore, the size of the apparatus is increased.

In the method (b), it is necessary to change the conductance-controlling plate to a proper one in order to obtain a conductance level for achieving a suitable radical flux.

In the methods (c) and (d), the conditions for generating plasma and the radical flux cannot be independently controlled.

Additionally, in all methods (a) to (d), it is very difficult to control the radical flux to an ultra-low level for allowing a several-molecular-layer surface of a substrate to be processed.

Japanese Patent Laid-Open No. 2005-142234 (corresponding to US Patent Appl. No. 2005-092,243) discloses a plasma-processing apparatus and a method for precisely controlling radicals excited by microwave plasma so that a low radical flux is applied to a substrate to be processed.

### SUMMARY OF THE INVENTION

The present invention is directed to a processing apparatus which can precisely control a radical flux over a broad range in radical treatment.

According to one aspect of the present invention, a processing apparatus includes a treatment chamber adapted to receive a substrate to be processed, a radical-forming portion configured to form radicals in a radical-generating region in the treatment chamber, a support supporting the substrate in the treatment chamber, a gas inlet facilitating introducing a reaction gas and being disposed between the support and the radical-generating region, a first gas outlet disposed at the side of the radical-generating region with respect to the gas inlet, and a second gas outlet disposed at the side of the support with respect to the gas inlet.

The processing apparatus according to the present invention may include at least one first conductance-controlling plate disposed between the radical-generating region and the gas inlet.

In addition, the processing apparatus may include at least one second conductance-controlling plate disposed between the substrate-support and the gas inlet.

The processing apparatus according to the present invention may include a controller controlling the kinetic energy of radicals in the passage for the transportation of the radicals toward a region in the treatment chamber where the substrate is placed.

The controller may be a temperature controller configured to heat or cool a wall surface of the treatment chamber in a region between the radical-generating region and the support.

The processing apparatus according to the present invention may include an inert-gas inlet disposed between the gas inlet and the substrate-support.

In the processing apparatus according to the present invention, the radical-forming portion forms the radicals by UV light excitation.

In addition, the radical-forming portion forms the radicals by plasma excitation.

Further features of the present invention will become apparent from the following description of exemplary embodiments with reference to the attached drawings.

### BRIEF DESCRIPTION OF THE DRAWINGS

FIG. 1 is a schematic diagram of a processing apparatus according to a First Exemplary Embodiment of the present invention.

FIG. 2 is a schematic diagram of a plasma-processing apparatus using an endless circular waveguide with slots according to a Second Exemplary Embodiment of the present invention.

FIG. 3 is a schematic diagram of a processing apparatus using a UV excitation radical source according to a Third Exemplary Embodiment of the present invention.

FIG. 4 is a schematic diagram of a plasma-processing apparatus provided with inert-gas inlets according to a Fourth Exemplary Embodiment of the present invention.

FIG. 5A is a schematic diagram of a processing apparatus according to a Fifth Exemplary Embodiment of the present invention.

FIG. 5B is a schematic diagram of a conductance-controlling plate having a heating mechanism in the plasma-processing apparatus according to the Fifth Exemplary Embodiment of the present invention.

FIG. 6 is a schematic diagram of a known processing apparatus.

### DESCRIPTION OF THE EMBODIMENTS

In a processing apparatus in accordance with the present invention, a first gas outlet is provided so that a reaction gas introduced from a gas inlet is discharged from a radical-treatment chamber after passing through a radical-generating region. In addition, a second gas outlet is provided so that the reaction gas introduced from the gas inlet is discharged from the treatment chamber after passing near the surface of a substrate-support.

Therefore, the radical density in the treatment chamber can be controlled over a broad range by adjusting the exhaust conductance ratio between the first gas outlet and the second gas outlet.

When a conductance valve provided on the second gas outlet is completely closed, the reaction gas introduced in the treatment chamber flows from the substrate side to the radical-generating region and is discharged from the first gas outlet.

Therefore, only radicals diffused from the radical-generating region against the flow of the reaction gas can be present in the vicinity of the substrate.

As a result, an ultra-low radical flux which cannot be performed by known apparatuses can be supplied to the substrate to be processed.

Furthermore, the flux can be readily controlled by adjusting the flow rate of the reaction gas. Therefore, the flux is also controllable by changing the exhaust conductance ratio between the first gas outlet and the second gas outlet.

The present invention will now be described according to the Embodiments of the invention with reference to the drawings.

### First Exemplary Embodiment

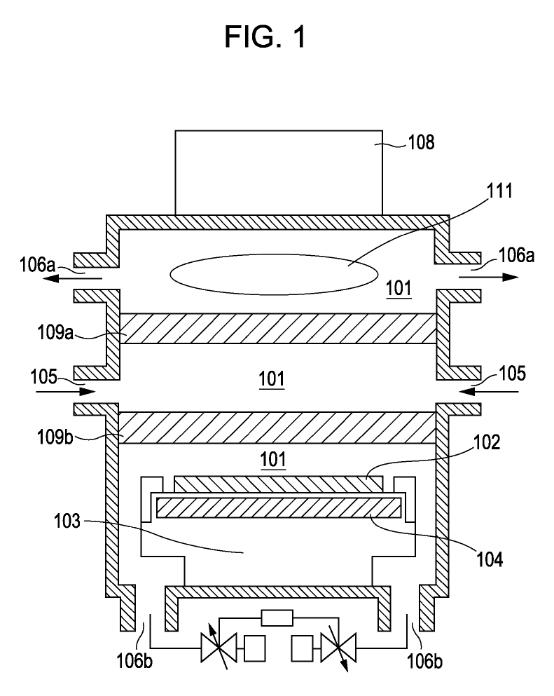

A processing apparatus according to a First Exemplary Embodiment of the present invention will be described with reference to FIG. 1.

In a treatment chamber 101, a surface of a substrate 102 such as a semiconductor is processed with radicals. A radical-forming unit 108 generates radicals in a radical-generating region 111 located in the upper region of the treatment chamber 101.

Gas inlets 105 are disposed at the lower side with respect to the radical-forming unit 108 and serve as mechanisms for introducing a reaction gas into the treatment chamber 101.

A substrate-support 103 is disposed at the lower side with respect to the gas inlets 105 and supports the substrate 102 to be processed.

In the First Exemplary Embodiment, the gas inlets 105 are disposed at the lower side with respect to the radical-forming unit 108, and the substrate-support 103 is disposed at the lower side with respect to the gas inlets 105. However, these positions can be changed as long as the gas inlets 105 are disposed between the radical-forming unit 108 and the substrate-support 103.

A heater 104 controls the temperature of the substrate 102 to be processed, which is placed on the substrate-support 103.

First gas outlets 106a are provided so that a reaction gas introduced from the gas inlets 105 is discharged from the upper portion of the treatment chamber 101 after passing through the radical-generating region 111.

Second gas outlets 106b are provided so that a reaction gas introduced from the gas inlets 105 is discharged from the lower portion of the treatment chamber 101 after passing near the surface of the substrate-support 103.

At least one first conductance-controlling plate 109a is disposed between the radical-generating region 111 and the gas inlets 105. The first conductance-controlling plate 109a has a function of controlling the kinetic energy of radicals by heating the reaction gas passing through the plate 109a.

At least one second conductance-controlling plate 109b is disposed between the substrate-support 103 and the gas inlets 105. The second conductance-controlling plate 109b has a function of controlling the kinetic energy of radicals by heating the reaction gas passing through the plate 109b.

The radical treatment of a surface of a substrate 102 to be processed is conducted by using the processing apparatus according to the First Exemplary Embodiment as follows.

At first, the radical-treatment chamber 101 is evacuated through the first gas outlets 106a and the second gas outlets 106b to produce vacuum conditions in the chamber 101.

Then, a reaction gas is introduced into the treatment chamber 101 at a predetermined flow rate through the gas inlets 105 disposed between the radical-generating region 111 and the substrate-support 103.

The pressure in the treatment chamber 101 is maintained at a predetermined level by controlling conductance valves (not shown) provided on the first gas outlets 106a and the second gas outlets 106b.

The radical-forming unit 108 is supplied with power necessary for forming radicals by exciting the reaction gas introduced into the treatment chamber 101.

At this stage, the radical density in the treatment chamber 101 can be controlled over a broad range by adjusting the exhaust conductance ratio between the first gas outlets 106a and the second gas outlets 106b.

For example, when conductance valves provided on the first gas outlets 106a are completely closed, the gas in the treatment chamber 101 flows from the radical-generating region 111 toward the substrate 102 and then is discharged through the second gas outlets 106b disposed at the lower portion of the treatment chamber 101. In this way, downflow conditions are produced and thereby treatment and process-control by a high radical flux can be achieved, like in known processing apparatuses.

When conductance valves provided on the second gas outlets 106b are completely closed, the reaction gas introduced in the radical-treatment chamber 101 flows from the substrate 102 side toward the radical-generating region 111 and is discharged through the first gas outlets 106a. Therefore, only radicals diffused from the radical-generating region 111 against the flow of the reaction gas can be present in the vicinity of the substrate 102.

As a result, an ultra-low radical flux which cannot be performed by known apparatuses can be supplied to the substrate 102 to be processed.

The flux can be readily controlled by adjusting the flow rate of the reaction gas. Similarly, the flux can be also controlled by changing the exhaust conductance ratio between the first gas outlets 106a and the second gas outlets 106b.

The processing apparatus according to the First Exemplary Embodiment of the present invention may be provided with a mechanism for controlling the kinetic energy of radicals in the passage for transporting the radicals to a region of the treatment chamber 101 where the substrate 102 is placed. This mechanism for controlling the kinetic energy of radicals may be a temperature controller for heating or cooling the wall surface of the treatment chamber 101 facing the radical-generating region 111.

The mechanism for controlling the kinetic energy of radials may be a temperature controller for heating or cooling at least part of the wall surface of the treatment chamber 101 facing the passage of the reaction gas flowing downward from the radical-generating region 111.

With the mechanism for controlling the kinetic energy of radicals, the recombination reaction rate of the diffusing radicals is controlled and therefore the controllability of fluxes can be further improved.

In addition, for further improving the controllability, the processing apparatus according to the First Exemplary Embodiment of the present invention may be provided with an inert-gas inlet at a position between the gas inlets 105 and the substrate-support 103.

Examples of the inert gas include noble gases (e.g., He, Ne, Ar, Kr, and Xe), N₂, and gas mixtures thereof.

The radical-forming unit 108 used in the processing apparatus according to the First Exemplary Embodiment of the present invention may be high-frequency plasma excitation, UV-light excitation, or a combination thereof.

In the high-frequency plasma excitation, any plasma excitation mechanism, such as capacitively coupled plasma (CCP), inductively coupled plasma (ICP), helicon waves, electron cyclotron resonance (ECR), a microwave, a surface wave, or surface-wave interfered plasma, may be employed.

In the UV-light excitation, any light source can be used as long as the source can emit light having excitation energy producing desired radicals.

Examples of the lamp include xenon short-arc lamps, xenon flash lamps, short-arc ultra-high-pressure mercury lamps, capillary lamps, and long-arc lamps.

In addition, low-pressure mercury lamps, Deep UV lamps, metal halide lamps, excimer lamps, nitrogen laser, and excimer laser may be used as the light source.

When an excimer lamp is used, the emission central wavelength varies depending on a sealing gas such as F₂, Cl₂, Br₂, I₂, ArBr, KrBr, XeBr, ArCl, KrCl, XeCl, ArF, KrF, XeF, or XeI.

Therefore, a sealing gas may be selected from these gases so that the emitted light has a wavelength most suitable for producing desired radicals.

The conductance-controlling plate may be made of a silicon-based insulating material such as quartz or silicon nitride when metal pollution is troublesome for a subject to be treated with radicals, for example, as in the formation of a gate oxide/nitride film of a MOS-FET.

When metal pollution is not troublesome but it is required to halt electromagnetic-wave irradiation to a substrate, a metal such as aluminum may be used. When both metal pollution and electromagnetic-wave irradiation are troublesome, a silicon-based insulating material containing a metal may be used.

In the radical treatment using the processing apparatus according to the First Exemplary Embodiment of the present invention, the pressure in the radical-treatment chamber is in the range of 1.3×10⁻² to 1333 Pa.

A pressure in the range of 1.3 to 667 Pa, i.e., a pressure of intermediate flow or viscous flow, is suitable. In particular, a pressure in the range of 133 to 400 Pa is further suitable for treating a several-molecular-layer surface.

The substrate 102 to be processed by using the processing apparatus according to the First Exemplary Embodiment of the present invention may be a semiconductor, an electrically conductive material, or an electrically insulative material. Examples of the electrically conductive substrate include metals such as Fe, Ni, Cr, Al, Mo, Au, Nb, Ta, V, Ti, Pt, and Pb; and alloys thereof such as brass and stainless steel. Examples of the electrically insulative substrate include SiO₂ quartz; various types of glass; and inorganic materials such as Si₃N₄, NaCl, KCl, LiF, CaF₂, BaF₂, Al₂O₃, AlN, and MgO. In addition, films of organic materials such as polyethylenes, polyesters, polycarbonates, cellulose acetates, polypropylenes, polyvinyl chlorides, polyvinylidene chlorides, polystyrenes, polyamides, and polyimides can be used.

When the surface of a substrate 102 is modified by using the processing apparatus according to the First Exemplary Embodiment of the present invention, the reaction gas is optionally selected.

For example, when a substrate 102 or the surface layer of a substrate 102 to be processed is made of Si, Al, Ti, Zn, or Ta, the substrate 102 or the surface layer of the substrate 102 can be subjected to oxidizing or nitriding, and also doping with B, As, or P.

The film formation employing the method using the processing apparatus according to the First Exemplary Embodiment of the present invention can be applied to cleaning of oxides, organic materials, or heavy metals.

When the surface of the substrate 102 is oxidized, examples of the oxidizing gas introduced through the reaction gas inlets 105 include O₂, O₃, H₂O, NO, N₂O, and NO₂. When the surface of the substrate 102 is nitrided, examples of the nitriding gas introduced through the reaction gas inlets 105 include N₂, NH₃, N₂H₄, and hexamethyldisilazane (HMDS).

When an organic material on the surface of a substrate 102 to be processed is subjected to cleaning or an organic material on the surface of a photoresist as a substrate 102 to be processed is removed by ashing, examples of the cleaning or ashing gas introduced through the gas inlets 105 include O₂, O₃, H₂O, NO, N₂O, NO₂, and H₂. When an inorganic material on the surface of a substrate 102 to be processed is subjected to cleaning, examples of the cleaning gas introduced through the gas inlets 105 include F₂, CF₄, CH₂F₂, C₂F₆, C₄F₈, CF₂Cl₂, SF₆, and NF₃.

When a deposition film is formed by using the processing apparatus according to the First Exemplary Embodiment of the present invention, the reaction gas is optionally selected.

By optionally selecting the reaction gas, for example, an insulating film made of Si₃N₄, SiO₂, SiOF, Ta₂O₅, TiO₂, TiN, Al₂O₃, AlN, or MgF₂ or a semiconductor film made of a-Si, poly-Si, SiC, or GaAs can be efficiently formed.

In addition, various deposition films such as metal films formed of Al, W, Mo, Ti, or Ta can be efficiently formed.

When a thin film is formed on a substrate by chemical vapor deposition (CVD), generally known gases can be used.

When a thin-film semiconductor made of a Si-based material such as a-Si, poly-Si, or SiC is formed, the reaction gas containing Si atoms introduced to the radical-treatment chamber 101 through the gas inlets 105 is as follows.

Inorganic silanes such as SiH₄ and Si₂H₆ and organic silanes such as tetraethylsilane (TES), tetramethylsilane (TMS), dimethylsilane (DMS), dimethyldifluorosilane (DMDFS), and dimethyldichlorosilane (DMDCS) may be used.

In addition, halosilanes such as SiF₄, Si₂F₆, Si₃F₈, SiHF₃, SiH₂F₂, SiCl₄, Si₂Cl₆, SiHCl₃, SiH₂Cl₂, SiH₃Cl, and SiCl₂F₂ may be used.

Materials which are gaseous or readily gasified at normal temperature and pressure may be used. In such a case, H₂, He, Ne, Ar, Kr, Xe, or Rn may be used as an additive gas or a carrier gas to be introduced as a gas mixture with the reaction gas supplying Si.

When a thin film made of a Si compound such as Si₃N₄ or SiO₂ is formed, examples of the reaction gas containing Si atoms introduced through the gas inlets 105 include inorganic silanes such as SiH₄ and Si₂H₆; organic silanes such as tetraethoxysilane (TEOS), tetramethoxysilane (TMOS), octamethylcyclotetrasilane (OMCTS), dimethyldifluorosilane (DMDFS), and dimethyldichlorosilane (DMDCS); halosilanes such as SiF₄, Si₂F₆, Si₃F₈, SiHF₃, SiH₂F₂, SiCl₄, Si₂Cl₆, SiHCl₃, SiH₂Cl₂, SiH₃Cl, and SiCl₂F₂; and materials which are gaseous or readily gasified at normal temperature and pressure.

In such a case, a nitriding gas or an oxidizing gas simultaneously introduced may be N₂, NH₃, N₂H₄, hexamethyldisilazane (HMDS), O₂, O₃, H₂O, NO, N₂O, or NO₂.

When a thin metal film made of Al, W, Mo, Ti, or Ta is formed, the reaction gas containing metal atoms introduced through the reaction gas inlets 105 is as follows.

Organic metals such as trimethylaluminum (TMAl), triethylaluminum (TEAl), triisobutylaluminum (TIBAl), dimethylaluminum halide (DMAlH), tungsten carbonyl (W(CO)₆), molybdenum carbonyl (Mo(CO)₆), trimethylgallium (TMGa), and triethylgallium (TEGa); and halogen metals such as AlCl₃, WF₆, TiCl₃, and TaCl₅ may be used.

In such a case, H₂, He, Ne, Ar, Kr, Xe, or Rn may be used as an additive gas or a carrier gas to be introduced as a gas mixture with the reaction gas supplying Si.

When a thin film made of a metal compound such as Al₂O₃, AlN, Ta₂O₅, TiO₂, TiN, or WO₃, the reaction gas containing metal atoms introduced through the reaction gas inlets 105 is as follows.

Organic metals such as trimethylaluminum (TMAl), triethylaluminum (TEAl), triisobutylaluminum (TIBAl), and dimethylaluminum halide (DMAlH) may be used.

In addition, organic metals such as tungsten carbonyl (W(CO)₆), molybdenum carbonyl (Mo(CO)₆), trimethylgallium (TMGa), and triethylgallium (TEGa); and halogen metals such as AlCl₃, WF₆, TiCl₃, and TaCl₅ may be used.

In such a case, an oxidizing gas or a nitriding gas simultaneously introduced may be O₂, O₃, H₂O, NO, N₂O, NO₂ N₂, NH₃, N₂H₄, or hexamethyldisilazane (HMDS).

When a substrate surface is etched, examples of the etching gas introduced through the reaction gas inlets 105 include F₂, CF₄, CH₂F₂, C₂F₆, C₃F₈, C₄F₈, CF₂Cl₂, SF₆, NF₃, Cl₂, CCl₄, CH₂Cl₂, and C₂Cl₆. When an organic material on a surface of a substrate 102 such as a photoresist is removed by ashing, examples of the ashing gas introduced through the reaction gas inlets 105 include O₂, O₃, H₂O, NO, N₂O, NO₂, and H₂.

### Second Exemplary Embodiment

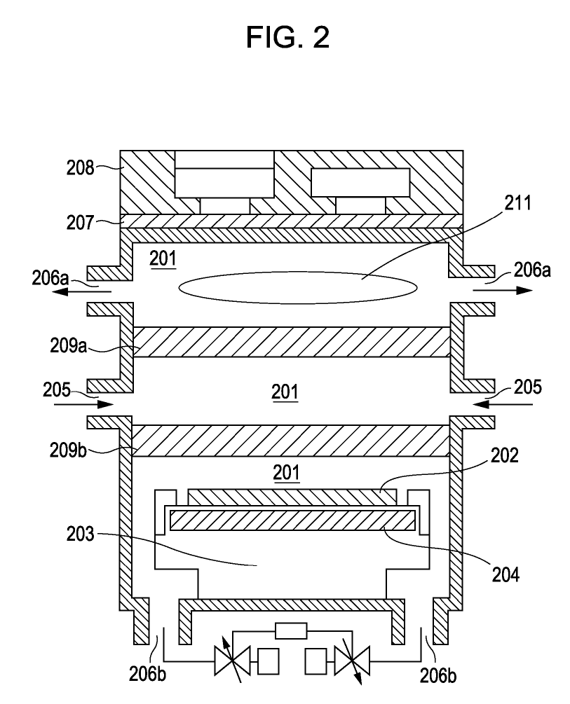

A microwave excitation surface-wave interfered plasma-processing apparatus using an endless circular waveguide with slots according to a Second Exemplary Embodiment of the present invention will now be described with reference to FIG. 2.

In a radical-treatment chamber 201, a surface of a substrate 202 such as a semiconductor is processed with radicals.

An endless circular waveguide 208 with slots serves as a radical-forming mechanism and also serves as a mechanism for introducing a microwave to the treatment chamber 201 through a microwave-transmitting unit 207.

The endless circular waveguide 208 with slots forms radicals in a radical-generating region 211 at the upper region of the treatment chamber 201.

Gas inlets 205 are disposed at the lower side with respect to the endless circular waveguide (radical-forming mechanism) 208 and serve as a mechanism for introducing a reaction gas into the treatment chamber 201.

A substrate-support 203 is disposed at the lower side with respect to the gas inlets 205 and supports a substrate 202 to be processed.

A heater 204 controls the temperature of the substrate 202 placed on the substrate-support 203.

First gas outlets 206a are provided so that a reaction gas introduced from the gas inlets 205 is discharged from the upper portion of the treatment chamber 201 after passing through the radical-generating region 211.

Second gas outlets 206b are provided so that a reaction gas introduced from the gas inlets 205 is discharged from the lower portion of the treatment chamber 201 after passing near the substrate-support 203.

At least one first conductance-controlling plate 209a is disposed between the radical-generating region 211 and the gas inlets 205. The first conductance-controlling plate 209a has a function of controlling the kinetic energy of radicals by heating the reaction gas passing through the plate 209a.

At least one second conductance-controlling plate 209b is disposed between the substrate-support 203 and the gas inlets 205. The second conductance-controlling plate 209b has a function of controlling the kinetic energy of radicals by heating the reaction gas passing through the plate 209b.

The first conductance-controlling plate 209a and the second conductance-controlling plate 209b are flat plates each provided with holes having a diameter of 1 to 3 mm at a pitch of about 20 mm. The plates 209a and 209b control the flow of introduced reaction gas and the diffusion of radicals.

In the Second Exemplary Embodiment, the shapes and the arrangement of the holes are optionally determined so that desired conductance is achieved.

The first conductance-controlling plate 209a and the second conductance-controlling plate 209b may be the same or different. Therefore, the diameters and the arrangement of the holes of both plates 209a and 209b may be the same or different.

The endless circular waveguide 208 with slots is the TE10 mode and has an inner cross-section of about 27 mm×96 mm (guide wavelength: 158.8 mm) and a central diameter of about 151.6 mm (circumferential length is 3 times the guide wavelength).

The endless circular waveguide 208 can be made of an Al alloy in order to suppress a propagation loss of the microwave.

The H face of the endless circular waveguide 208 is provided with slots for introducing a microwave to the radical-treatment chamber 201.

Each slot can be a rectangle having a length of about 40 mm and a width of about 4 mm. Six slots are radially arranged at intervals of about 60° at the position with a central diameter of about 151.6 mm.

The endless circular waveguide 208 with slots is connected to a 4E tuner, a directional coupler, an isolator, and a microwave power supply (not shown) in this order.

The microwave power supply may be a magnetron and generates a microwave having a frequency of 2.45 GHz, for example.

In the Second Exemplary Embodiment, the frequency of the microwave may be 0.8 to 20 GHz, for example.

The radical-treatment chamber 201 in the Second Exemplary Embodiment is a vacuum container that receives (holds) the substrate 202 to be processed and provides a radical treatment to the substrate 202 under a reduced pressure or vacuum environment.

In the Second Exemplary Embodiment shown in FIG. 2, a gate valve for transporting the substrate 202 from and to a load lock chamber (not shown) is omitted.

A substrate 202 is placed on the substrate-support 203. The substrate-support 203 is disposed in the treatment chamber 201 and supports the substrate 202.

The heater 204 controls the temperature of a substrate 202 to a temperature suitable for being processed, for example, to a temperature range of 200 to 400° C.

The heater 204 may have, for example, a temperature gauge for measuring the temperature of the substrate-support 203 and a controller for controlling the temperature of the substrate-support 203 to a predetermined temperature. The controller, as a temperature regulator, controls power distribution to heater wires from a power supply (not shown).

The gas inlets 205 are disposed between the radical-generating region 211 and the substrate-support 203 and supply a reaction gas for plasma treatment to the treatment chamber 201.

The gas inlets 205 are a part of a gas-supplying mechanism. The gas-supplying mechanism is composed of a gas-supplying source, a valve, a mass flow controller, and gas pipes connecting therewith.

The gas inlets 205 supply a reaction gas or a discharge gas which generates predetermined plasma by microwave excitation. A noble gas such as Xe, Ar, or He may be added to the reaction gas at least when plasma is ignited for rapid ignition of the plasma. Since noble gases are inert, the substrate 202 does not receive any negative effect. In addition, noble gases are readily ionized to raise the ignition rate of the plasma when the microwave is introduced.

The gas inlets 205 may include an introduction portion for introducing a reaction gas and an introduction portion for introducing an inert gas so that the introduction portions are arranged at separate positions.

The first conductance-controlling plate 209a for controlling a radical flux is disposed between the gas inlets 205 and the radical-generating region 211. The first conductance-controlling plate 209a controls a radical flux diffused from the radical-generating region 211 and rectifies the gas.

The second conductance-controlling plate 209b is disposed between the gas inlets 205 and the substrate-support 203 for supporting a substrate 202.

The second conductance-controlling plate 209b controls a radical flux diffused from the radical-generating region 211 and rectifies the gas.

The first gas outlets 206a are disposed at the periphery of the radical-generating region 211. The second gas outlets 206b are disposed at the periphery of the region where a substrate 202 is processed. The first gas outlets 206a and the second gas outlets 206b are each composed of a pressure gauge, a controller, a pressure-regulating mechanism, and a vacuum pump (not shown).

The pressure gauge (not shown) detects the pressure in the treatment chamber 201 and the controller (not shown) controls the pressure in the treatment chamber 201 to a predetermined level by driving the vacuum pump.

The pressure in the treatment chamber 201 may be controlled by adjusting the degree of opening of the pressure-regulating valve (for example, a gate valve with a pressure regulator manufactured by VAT Co. or a discharge throttle valve manufactured by MKS Instrument Inc.).

Consequently, the pressure in the treatment chamber 201 can be controlled by the pressure-regulating mechanism to a level suitable for the processing.

The flow rates of the gas discharged through the gas outlets can be independently controlled. Therefore, the flow direction of the gas introduced through the gas inlets 205 can be controlled by changing the flow rates of the gas discharged through the gas outlets.

For example, when the flow rate of the gas discharged through the first gas outlets 206a is higher than that through the second gas outlets 206b, the gas strongly flows from the gas inlets 205 toward the radical-generating region 211 and then is discharged.

The plasma treatment in the Second Exemplary Embodiment is conducted as follows.

The treatment chamber 201 is evacuated through the first gas outlets 206a and the second gas outlets 206b to produce vacuum conditions in the chamber 201.

Then, a reaction gas is introduced into the treatment chamber 201 at a predetermined flow rate through the gas inlets 205.

The pressure in the treatment chamber 201 is maintained at a predetermined level and the gas flow generated in the treatment chamber 201 is controlled by adjusting conductance valves (not shown) provided on pipes connected to the first gas outlets 206a and the second gas outlets 206b.

A microwave power supply (not shown) supplies a predetermined power to the treatment chamber 201 via the endless circular waveguide 208 with slots and the microwave-transmitting unit 207.

The generated plasma excites and ionizes the reaction gas introduced through the gas inlets 205 so as to generate radicals in the radical-generating region 211.

The generated radicals are transported by diffusion. Only the radicals which reach the surface of a substrate 202 on the substrate-support 203 provide the radical treatment to the surface of the substrate.

The direction of diffusion of the radicals highly depends on a gas flow determined by the discharged gas flow ratio between the first gas outlets 206a and the second gas outlets 206b.

The flux of the radicals reaching the surface of the substrate 202 can be optionally controlled by changing the flow rate of the introduced gas and the pressure in the treatment chamber 201.

For example, when the discharge from the first gas outlets 206a is completely closed, the reaction gas introduced through the gas inlets 205 flows to the region where the substrate 202 is processed and then is discharged from the second gas outlets 206b.

The radicals generated in the radical-generating region 211 are transported toward the substrate according to this gas flow. Consequently, a large radical flux can be supplied to the region where the substrate 202 is processed.

When the discharge from the second gas outlets 206b is completely closed, the reaction gas introduced through the gas inlets 205 flows to the radical-generating region 211 and is discharged from the first gas outlets 206a.

The radicals generated in the radical-generating region 211 are mostly discharged according to this gas flow, without reaching the substrate 202. Therefore, the region where the substrate 202 is processed can be supplied with an ultra-low flux of the radicals which are diffused against the gas flow.

Thus, the gas-discharging rates through the first gas outlets 206a and the second gas outlets 206b can be controlled, and thereby a substrate 202 can be supplied and processed with the radical flux over a broad range, i.e., from a high radical flux to an ultra-low radical flux which cannot be achieved by known processing apparatuses.

An ultra-thin oxide film was formed by oxidizing a silicon semiconductor substrate by using a microwave plasma processing apparatus shown in FIG. 2 according to the Second Exemplary Embodiment of the present invention.

The endless circular waveguide 208 with slots is a mechanism for introducing a microwave to the treatment chamber 201 through dielectric windows (microwave-transmitting unit) 207.

The endless circular waveguide 208 with slots was the TE10 mode and had an inner cross-section of about 27 mm×96 mm (guide wavelength: 158.8 mm) and a central diameter of about 151.6 mm (circumferential length is 3 times the guide wavelength).

The endless circular waveguide 208 was made of an Al alloy in order to suppress a propagation loss of the microwave.

The H face of the endless circular waveguide 208 was provided with slots for introducing a microwave to the treatment chamber 201.

Each slot was a rectangle having a length of about 40 mm and a width of about 4 mm. Six slots were radially arranged at intervals of about 60° at the position with a central diameter of about 151.6 mm.

The endless circular waveguide 208 was connected to a 4E tuner, a directional coupler, an isolator, and a microwave power supply (not shown) having a frequency of 2.45 GHz in this order.

The first conductance-controlling plate 209a and the second conductance-controlling plate 209b were flat quartz plates each having a thickness of about 5 mm and were each provided with holes having a diameter of about 1 mm at a pitch of about 15 mm.

As a substrate 202 to be processed, an 8-inch P-type monocrystalline silicon substrate (face orientation: <100>, resistivity: 10 Ωcm) was used.

The silicon substrate 202 was conveyed to the treatment chamber 201 and placed on the substrate-support 203.

The silicon substrate 202 was heated by the heater 204 to 300° C. and the temperature was maintained.

The treatment chamber 201 was evacuated to 10⁻⁷ Torr through the first gas outlets 206a and the second gas outlets 206b.

Oxygen gas was introduced to the treatment chamber 201 at a flow rate of 2000 sccm. Then, conductance valves provided on the second gas outlets 206b were completely closed.

The pressure in the treatment chamber 201 was maintained at 400 Pa by adjusting the degree of opening of the conductance valves provided on the first gas outlets 206a.

A microwave power of 2.45 GHz with 3 kW was applied in the treatment chamber 201 via the endless circular waveguide 208 with slots and the dielectric windows 207 to generate plasma. An extremely small amount of the generated atomic oxygen radicals were transported toward the silicon substrate 202 against the flow of the introduced gas to oxidize the surface of the silicon substrate 202.

The silicon substrate 202 was left for 3 min so as to be exposed to the radicals. Thus, a silicon oxide film was formed. The resulting silicon oxide film was measured with an ellipsometer to have a thickness of about 1.6 nm.

After the treatment, the uniformity, pressure resistance, and leakage current density of the film were evaluated to confirm the good quality of a uniformity of ±1.7%, a pressure resistance of 12.3 MV/cm, and a leakage current density of 9.5×10⁻⁴ A/cm² at 1 V.

A thick oxide film was formed by oxidizing a silicon semiconductor substrate by using a microwave plasma processing apparatus shown in FIG. 2 according to the Second Exemplary Embodiment of the present invention.

As a substrate 202 to be processed, an 8-inch P-type monocrystalline silicon substrate (face orientation: <100>, resistivity: 10 Ωcm) was used.

The silicon substrate 202 was conveyed to the treatment chamber 201 and placed on the substrate-support 203.

The silicon substrate 202 was heated by the heater 204 to 400° C. and the temperature was maintained.

The treatment chamber 201 was evacuated to 10⁻⁷ Torr through the first gas outlets 206a and the second gas outlets 206b.

Oxygen gas was introduced to the treatment chamber 201 through the gas inlets 205 at a flow rate of 250 sccm, and argon gas as an additive gas was introduced to the treatment chamber 201 through the gas inlets 205 at a flow rate of 250 sccm.

Then, the conductance valves provided on the first gas outlets 206a were completely closed.

The pressure in the treatment chamber 201 was maintained at 13.3 Pa by adjusting the degree of opening of the conductance valves provided on the second gas outlets 206b.

A microwave power of 2.45 GHz with 3 kW was applied in the treatment chamber 201 via a microwave-supplying unit, i.e., the endless circular waveguide 208 with slots and the dielectric windows 207, to generate plasma.

The generated atomic oxygen radicals were transported toward the silicon substrate 202 according to the flow of the introduced gas to oxidize the surface of the silicon substrate 202. The silicon substrate 202 was left for 5 min so as to be exposed to the radicals. Thus, a silicon oxide film was formed.

The resulting silicon oxide film was measured with an ellipsometer to have a thickness of about 10.5 nm.

After the treatment, the uniformity, pressure resistance, and interface state density of the film were evaluated to confirm the good quality of a uniformity of ±2.6%, a pressure resistance of 14.1 MV/cm, and an interface state density of 9.9×10⁻¹⁰ cm⁻² eV⁻¹.

### Third Exemplary Embodiment

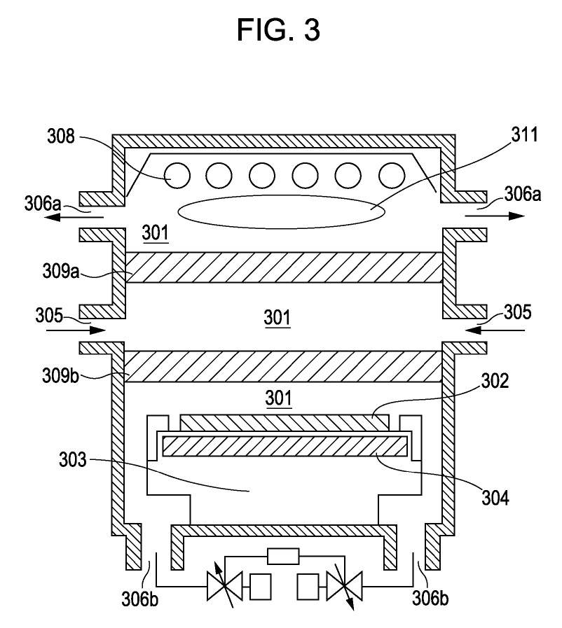

A UV-excitation radical processing apparatus according to a Third Exemplary Embodiment of the present invention will now be described with reference to FIG. 3.

In a treatment chamber 301, a surface of a substrate 302 such as a semiconductor is processed with radicals. A UV light source serving as a radical-forming unit 308 emits UV light by an application of power. The reaction gas is excited by the UV light to generate radicals in a radical-generating region 311 at the upper portion of the treatment chamber 301.

Gas inlets 305 are disposed at the lower side with respect to the radical-forming unit 308 and serve as a mechanism for introducing a reaction gas into the treatment chamber 301.

A substrate-support 303 is disposed at the lower side with respect to the gas inlets 305 and supports a substrate 302 to be processed.

A heater 304 controls the temperature of the substrate 302 disposed on the substrate-support 303.

First gas outlets 306a are provided so that a reaction gas introduced from the gas inlets 305 is discharged from the upper portion of the treatment chamber 301 after passing through the radical-generating region 311.

Second gas outlets 306b are provided so that a reaction gas introduced from the gas inlets 305 is discharged from the lower portion of the treatment chamber 301 after passing near the substrate-support 303 and then.

At least one first conductance-controlling plate 309a is disposed between the radical-generating region 311 and the gas inlets 305. The first conductance-controlling plate 309a has a function of controlling the kinetic energy of radicals by heating the reaction gas passing through the plate 309a.

At least one second conductance-controlling plate 309b is disposed between the substrate-support 303 and the gas inlets 305. The second conductance-controlling plate 309b has a function of controlling the kinetic energy of radicals by heating the reaction gas passing through the plate 309b.

The first conductance-controlling plate 309a and the second conductance-controlling plate 309b can be flat aluminum plates each provided with holes having a diameter of 3 to 5 mm at a pitch of 15 mm.

The radical treatment in the Third Exemplary Embodiment is conducted as follows.

The treatment chamber 301 is evacuated through a gas-discharging system (not shown) to produce vacuum conditions in the chamber 301.

Then, a reaction gas is introduced into the treatment chamber 301 at a predetermined flow rate through the gas inlets 305.

The pressure in the treatment chamber 301 is maintained at a predetermined level by adjusting conductance valves (not shown) provided on the gas-discharging system. A predetermined power is applied to the UV light source 308 so that UV light is emitted.

The reaction gas introduced through the gas inlets 305 absorbs the energy of the UV light emitted from the UV light source 308 to be excited and generate active radicals.

The generated radicals are transported by diffusion. Only the radicals which reach the surface of a substrate 302 on the substrate-support 303 provide the radical treatment to the surface of the substrate.

The direction of diffusion of the radicals highly depends on a gas flow determined by the discharged gas flow ratio between the first gas outlets 306a and the second gas outlets 306b.

The flux of the radicals reaching the surface of the substrate 302 can be optionally controlled by changing the flow rate of the introduced gas and the pressure in the radical-treatment chamber 301.

In the Third Exemplary Embodiment, the first conductance-controlling plate 309a and the second conductance-controlling plate 309b are made of aluminum.

Therefore, the first conductance-controlling plate 309a and the second conductance-controlling plate 309b shield UV light emitted from the UV light source 308. Consequently, the substrate 302 is not directly exposed to the UV light.

As a result, the film formed on the surface of the substrate 302 is not degraded by the UV light with a high energy so that film formation and surface treatment can be achieved with high quality.

An ultra-thin oxide film was formed by oxidizing a silicon semiconductor substrate by using the UV-excitation processing apparatus shown in FIG. 3 according to the Third Exemplary Embodiment of the present invention.

As the UV light source 308, a low-pressure mercury lamp which can activate oxygen gas to active atomic radicals was used.

The first conductance-controlling plate 309a and the second conductance-controlling plate 309b were flat plates covered with quartz.

Therefore, the UV light emitted from the UV light source 308 does not permeate to the substrate 302. Consequently, the substrate 302 does not receive negative effects from the UV light.

The surfaces of the first conductance-controlling plate 309a and the second conductance-controlling plate 309b were each provided with holes each having a diameter of 1 mm at a pitch of 15 mm. As a substrate 302 to be processed, an 8-inch P-type monocrystalline silicon substrate (face orientation: <100>, resistivity: 10 Ωcm) was used.

The silicon substrate 302 was placed on the substrate-support 303. The treatment chamber 301 was evacuated to 10⁻⁷ Torr through the first gas outlets 306a and the second gas outlets 306b.

The silicon substrate 302 was heated to 400° C. by energizing the heater 304 and this temperature of the silicon substrate 302 was maintained.

Oxygen gas was introduced to the radical-treatment chamber 301 at a flow rate of 1000 sccm through the gas inlets 305.

Then, conductance valves provided on the second gas outlets 306b were completely closed.

The pressure in the treatment chamber 301 was maintained at 400 Pa by adjusting the degree of opening of the conductance valves provided on the first gas outlets 306a.

A power of 300 W was applied to the UV light source (low-pressure mercury lamp) 308 so that UV light was emitted. UV light having a wavelength of 254 nm emitted from the low-pressure mercury lamp 308 can ionize oxygen gas into active single oxygen atoms.

Thus, atomic oxygen radicals were generated in the treatment chamber 301. An extremely small part of the generated atomic oxygen radicals were transported toward the silicon substrate 302 against the flow of the introduced gas. The surface of the silicon substrate 302 was oxidized by a thickness of about 0.8 nm.

After the treatment, the uniformity and pressure resistance of the film were evaluated to confirm the good quality of a uniformity of ±1.3% and a pressure resistance of 10.9 MV/cm.

### Fourth Exemplary Embodiment

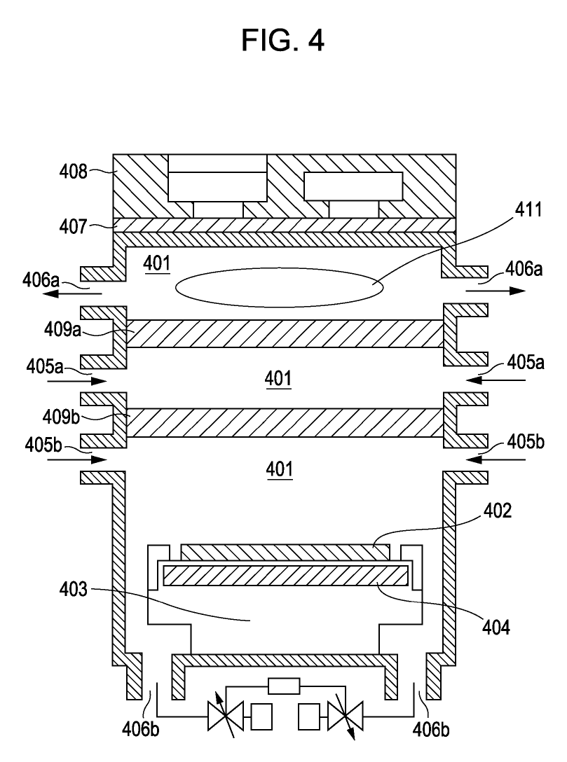

A processing apparatus provided with inert-gas inlets at the substrate-support side according to a Fourth Exemplary Embodiment of the present invention will now be described with reference to FIG. 4.

In a treatment chamber 401, a surface of a substrate 402 such as a semiconductor wafer is processed with radicals.

An endless circular waveguide 408 with slots serves as a radical-forming mechanism and also serves as a mechanism for introducing a microwave to the treatment chamber 401 through a microwave-transmitting unit 407.

The endless circular waveguide 408 with slots generates radicals in a radical-generating region 411 at the upper region of the treatment chamber 401.

Gas inlets 405a are disposed at the lower side with respect to the endless circular waveguide 408 serving as a radical-forming mechanism and serve as a mechanism for introducing a reaction gas into the treatment chamber 401.

A substrate-support 403 is disposed at the lower side with respect to the gas inlets 405a and supports a substrate 402 to be processed.

A heater 404 controls the temperature of a substrate 402 placed on the substrate-support 403.

First gas outlets 406a are provided so that a reaction gas introduced from the gas inlets 405a is discharged from the upper portion of the treatment chamber 401 after passing through the radical-generating region 411.

Second gas outlets 406b are provided so that a reaction gas introduced from the gas inlets 405a is discharged from the lower portion of the treatment chamber 401 after passing near the substrate-support 403.

At least one first conductance-controlling plate 409a is disposed between the radical-generating region 411 and the gas inlets 405. The first conductance-controlling plate 409a has a function of controlling the kinetic energy of radicals by heating the reaction gas passing through the plate 409a.

At least one second conductance-controlling plate 409b is disposed between the substrate-support 403 and the gas inlets 405. The second conductance-controlling plate 409b has a function of controlling the kinetic energy of radicals by heating the reaction gas passing through the plate 409b.

The first conductance-controlling plate 409a and the second conductance-controlling plate 409b can be made of quartz.

In the Fourth Exemplary Embodiment, inert-gas inlets 405b are provided between the gas inlets 405a and the substrate-support 403 and at a lower side with respect to the second conductance-controlling plate 409b.

The plasma treatment according to the Fourth Exemplary Embodiment is conducted as follows.

The treatment chamber 401 is evacuated through the first gas outlets 406a and the second gas outlets 406b to produce vacuum conditions in the chamber 401.

Then, a reaction gas is introduced into the treatment chamber 401 at a predetermined flow rate through the gas inlets 405a.

An inert gas is introduced into the treatment chamber 401 at a predetermined flow rate through the inert-gas inlets 405b.

The pressure in the treatment chamber 401 is maintained at a predetermined level by adjusting conductance valves (not shown) provided on the first gas outlets 406a and the second gas outlets 406b. Simultaneously, the gas flow generated in the treatment chamber 401 is controlled.

A predetermined power from the microwave power source (not shown) is supplied to the treatment chamber 401 via the endless circular waveguide 408 with slots and the microwave-transmitting unit 407.

The reaction gas introduced through the gas inlets 405a is excited and ionized by the generated plasma and reacts to generate active radicals in the radical-generating region 411.

The generated radicals are transported by diffusion. Only the radicals which reach the surface of a substrate 402 on the substrate-support 403 provide the radical treatment to the surface.

The direction of diffusion of the radicals highly depends on a gas flow determined by the discharged gas flow ratio between the first gas outlets 406a and the second gas outlets 406b.

The flux of the radicals reaching the surface of a substrate 402 can be optionally controlled by changing the flow rate of the introduced gas and the pressure in the treatment chamber 401.

An inert gas is introduced through the inert-gas inlets 405b disposed at the substrate 402 side with respect to the gas inlets 405a in the treatment chamber 401 to achieve dilution and purge effects. Therefore, the substrate 402 can be supplied with further lower flux of radicals.

A nitride film was formed by nitrizing a silicon semiconductor substrate by using a microwave plasma processing apparatus shown in FIG. 4 according to the Fourth Exemplary Embodiment of the present invention.

As a substrate 402 to be processed, an 8-inch P-type monocrystalline silicon substrate (face orientation: <100>, resistivity: 10 Ωcm) was used.

The silicon substrate 402 was conveyed to the treatment chamber 401 and placed on the substrate-support 403. The silicon substrate 402 was heated by the heater 404 to 300° C. and the temperature was maintained.

Nitrogen gas was introduced through the gas inlets 405a at a flow rate of 100 sccm and helium gas was introduced through the inert-gas inlets 405b at a flow rate of 1000 sccm in the treatment chamber 401.

Then, the degrees of opening of conductance valves were adjusted so that the flow rates of the gas discharged through the first gas outlets 406a and the second gas outlets 406b were almost the same and that the pressure in the treatment chamber 401 was maintained at 400 Pa.

A microwave power of 2.45 GHz with 3 kW was applied in the treatment chamber 401 via the endless circular waveguide 408 with slots as a microwave-supplying mechanism and the dielectric windows 407 as a microwave-transmitting mechanism to generate plasma.

The silicon substrate 402 was left for 5 min so as to be exposed to the generated nitrogen radicals to form a silicon nitride film having a thickness of about 2.0 nm.

After the treatment, the uniformity, pressure resistance, and leakage current density of the film were evaluated to confirm the good quality of a uniformity of ±2.0%, a pressure resistance of 15.8 MV/cm, and a leakage current density of 6.8×10⁻⁶ A/cm² at 1 V.

### Fifth Exemplary Embodiment

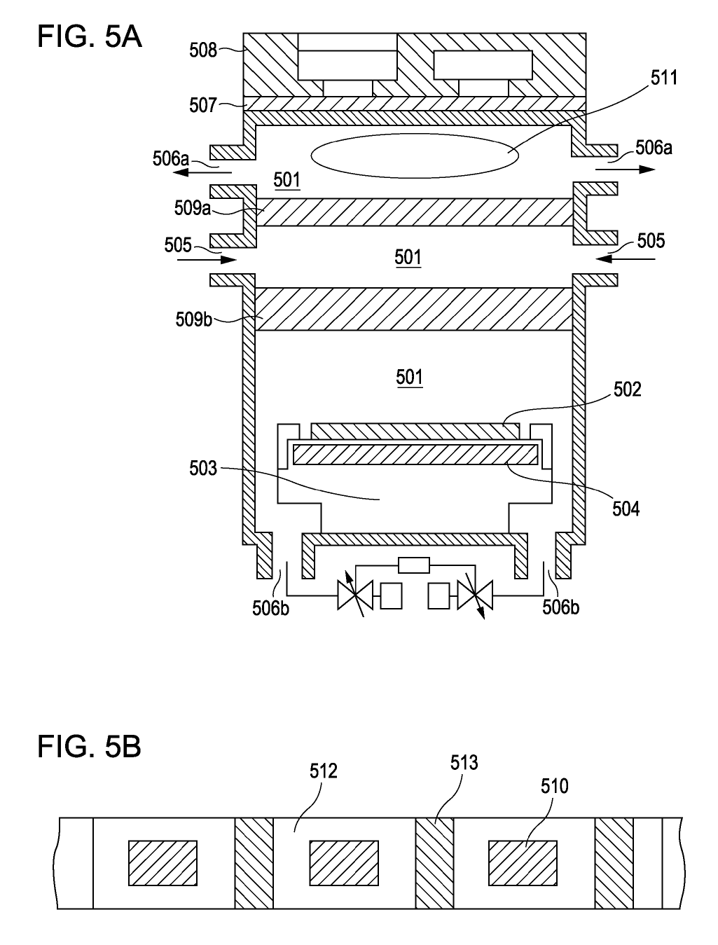

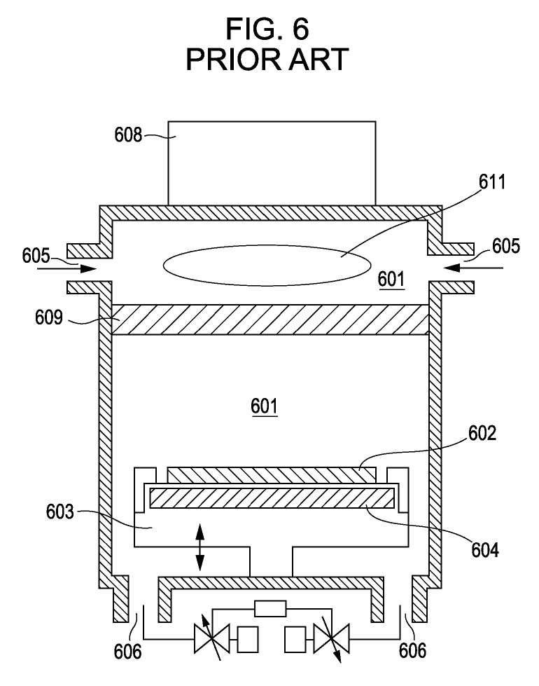

A processing apparatus provided with a gas-temperature controller according to a Fifth Exemplary Embodiment of the present invention will now be described with reference to FIG. 5A.

In a treatment chamber 501, a surface of a substrate 502 such as a semiconductor to be processed is treated with radicals. An endless circular waveguide 508 with slots serves as a radical-forming mechanism and also serves as a mechanism for introducing a microwave to the treatment chamber 501 through a microwave-transmitting unit 507.

The endless circular waveguide 508 with slots serving as the radical-forming mechanism generates radicals in a radical-generating region 511 at the upper region of the treatment chamber 501.

Gas inlets 505 are disposed at the lower side with respect to the endless circular waveguide (radical-forming unit) 508 and serve as a mechanism for introducing a reaction gas into the treatment chamber 501.

A substrate-support 503 is disposed at the lower side with respect to the gas inlets 505 and supports a substrate 502 to be processed.

A heater 504 controls the temperature of a substrate 502 placed on the substrate-support 503.

First gas outlets 506a are provided so that a reaction gas introduced from the gas inlets 505 is discharged from the upper portion of the treatment chamber 501 after passing through the radical-generating region 511.

Second gas outlets 506b are provided so that a reaction gas introduced from the gas inlets 505 is discharged from the lower portion of the treatment chamber 501 after passing near the substrate-support 503.

At least one first conductance-controlling plate 509a is disposed between the radical-generating region 511 and the gas inlets 505. The first conductance-controlling plate 509a has a function of controlling the kinetic energy of radicals by heating the reaction gas passing through the plate 509a.

At least one second conductance-controlling plate 509b is disposed between the substrate-support 503 and the gas inlets 505. The second conductance-controlling plate 509b has a function of controlling the kinetic energy of radicals by heating the reaction gas passing through the plate 509b.

As shown in FIG. 5B, the first conductance-controlling plate 509a and the second conductance-controlling plate 509b are flat plates each composed of a heating unit 510 covered with a covering material 512 and provided with through-holes 513. The heating unit 510 is provided with a temperature sensor (not shown) and a temperature controller (not shown) for controlling the temperature within a predetermined range.

The radical treatment in the Fifth Exemplary Embodiment is conducted as follows.

The treatment chamber 501 is evacuated through the first gas outlets 506a and the second gas outlets 506b to produce vacuum conditions in the chamber 501.

Then, a reaction gas is introduced into the treatment chamber 501 at a predetermined flow rate through the gas inlets 505.

The pressure in the treatment chamber 501 is maintained at a predetermined level and the gas flow generated in the treatment chamber 501 is controlled by adjusting conductance valves (not shown) provided on the first gas outlets 506a and the second gas outlets 506b.

A predetermined power from a microwave power source (not shown) is supplied to the treatment chamber 501 via the endless circular waveguide 508 with slots and a microwave-transmitting unit 507.

The reaction gas introduced through the gas inlets 505 is excited and ionized to react for generating active radicals in the radical-generating region 511.

The generated radicals are transported by diffusion. Only the radicals which reach the surface of a substrate 502 on the substrate-support 503 provide the radical treatment to the surface of the substrate.

The direction of diffusion of the radicals highly depends on a gas flow determined by the discharged gas flow ratio between the first gas outlets 506a and the second gas outlets 506b.

The flux of the radicals reaching the surface of a substrate 502 can be optionally controlled by changing the flow rate of the introduced gas and the pressure in the radical-treatment chamber 501.

The heating unit provided on the first conductance-controlling plate 509a and the second conductance-controlling plate 509b heat the radicals being transported by diffusion. Therefore, the rate of radical inactivation caused by recombination among the atomic radicals can be controlled. Consequently, the radical flux supplied to a substrate 502 to be processed can be controlled.

An oxynitride film was formed by oxidizing and nitrizing a substrate 502 of a silicon semiconductor by using the microwave plasma processing apparatus shown in FIG. 5A according to the Fifth Exemplary Embodiment of the present invention.

The first conductance-controlling plate 509a and the second conductance-controlling plate 509b were provided with heaters shown in FIG. 5B and were heated to 200 to 400° C. The temperature was maintained.

As a substrate 502 to be processed, an 8-inch P-type monocrystalline silicon substrate (face orientation: <100>, resistivity: 10 Ωcm) was used.

The silicon substrate 502 was conveyed to the treatment chamber 501 and was placed on the substrate-support 503.

The silicon substrate 502 was heated to 300° C. by the heater 504 and this temperature of the silicon substrate 502 was maintained.

The treatment chamber 501 was evacuated to 10⁻⁷ Torr through the first gas outlets 506a and the second gas outlets 506b.

Oxygen gas was introduced to the treatment chamber 501 at a flow rate of 2000 sccm through the gas inlets 505.

Then, conductance valves provided on the second gas outlets 506b were completely closed. The pressure in the treatment chamber 501 was maintained at 400 Pa by adjusting the degree of opening of the conductance valves provided on the first gas outlets 506a.

A microwave power of 2.45 GHz with 3 kW was applied in the treatment chamber 501 via a radical-forming mechanism, i.e., the endless circular waveguide (microwave-supplying unit) 508 and the dielectric windows 507. Thus, plasma was generated.

The oxygen radicals in the plasma are transported by diffusion to the region where a substrate 502 to be processed is placed. The oxygen radicals are heated when they pass through the first conductance-controlling plate 509a and the second conductance-controlling plate 509b disposed in the passage of the oxygen radicals.

The rate of radical inactivation caused by recombination among the atomic oxygen radicals depends on the heating temperature and thereby the radical flux can be controlled.

The silicon substrate 502 to be processed was left for 3 min so as to be exposed to the thus controlled flux of the radicals to form a silicon oxide film.

Then, after the treatment chamber 501 was sufficiently evacuated through the first gas outlets 506a and the second gas outlets 506b to 10⁻³ Pa, nitrogen gas was introduced into the treatment chamber 501 at a flow rate of 1000 sccm.

The conductance valves provided on the first gas outlets 506a were completely closed. The pressure in the treatment chamber 501 was maintained at 133 Pa by adjusting the degree of opening of the conductance valves provided on the second gas outlets 506b.

Then, a microwave power of 2.45 GHz with 3 kW was applied in the treatment chamber 501 via the radical-forming unit, i.e., the endless circular waveguide (microwave-supplying unit) 508 with slots and the dielectric windows 507. Thus, plasma was generated.

The silicon substrate 502 was left for 1 min for nitriding treatment so that the silicon oxide film formed on the silicon substrate 502 was exposed to the generated nitrogen radicals.

After the treatment, the uniformity and leakage current density of the film were evaluated to confirm the good quality of a uniformity of ±2.3% and a leakage current density of 5.2×10⁻⁵ A/cm² at 1 V. An equivalent oxide thickness (EOT) was about 1.5 nm.

While the present invention has been described with reference to exemplary embodiments, it is to be understood that the invention is not limited to the disclosed exemplary embodiments. The scope of the following claims is to be accorded the broadest interpretation so as to encompass all modifications, equivalent structures and functions.

According to the present invention, a processing apparatus is provided which can precisely control a radical flux over a broad range, from a high flow rate to an ultra-low flow rate, in the radical treatment of a surface of a substrate to be processed.

This application claims the benefit of Japanese Application No. 2005-275047 filed Sep. 22nd, 2005, which is hereby incorporated by reference herein in its entirety.

What is claimed is:

1. A processing apparatus comprising:
a treatment chamber adapted to receive a substrate to be processed;
a support supporting the substrate in the treatment chamber;
a radical-forming portion configured to form radicals in a radical-generating region in the treatment chamber;
a gas inlet facilitating introducing a reaction gas and being disposed between the support and the radical-generating region;
a first gas outlet disposed at the side of the radical-generating region with respect to the gas inlet; and
a second gas outlet disposed at the side of the support with respect to the gas inlet.

2. The processing apparatus according to claim 1, wherein the first gas outlet and the second gas outlet are each connected to a pipe having a conductance valve.

3. The processing apparatus according to claim 1, wherein the second gas outlet is disposed in such a manner that the distance between the second gas outlet and the gas inlet is longer than that between the support and the gas inlet.

4. The processing apparatus according to claim 1, further comprising a first conductance-controlling plate disposed between the radical-generating region and the gas inlet.

5. The processing apparatus according to claim 1, further comprising a second conductance-controlling plate disposed between the support and the gas inlet.

6. The processing apparatus according to claim 1, further comprising a controller configured to control the kinetic energy of radicals disposed between the radical-generating region and the support.

7. The processing apparatus according to claim 6, wherein the controller includes a temperature controller configured to heat or cool at least part of a wall surface of the treatment chamber in a region between the radical-generating region and the support.

8. The processing apparatus according to claim 1, further comprising an inert-gas inlet disposed between the gas inlet and the support.

9. The processing apparatus according to claim 1, wherein the radical-forming portion forms the radicals by UV light excitation.

10. The processing apparatus according to claim 1, wherein the radical-forming portion forms the radicals by plasma excitation.
